(19) United States
(12) Patent Application Publication
(10) Pub. No.: US 2017/0193942 A1
(43) Pub. Date: Jul. 6, 2017

(54) GOA CIRCUIT STRUCTURE FOR SLIM-BEZEL LCD

(71) Applicant: Shenzhen China Star Optoelectronics Technology Co., Ltd., Shenzhen City (CN)

(72) Inventors: Wenying Li, Shenzhen City (CN); Sikun Hao, Shenzhen City (CN)

(21) Appl. No.: 14/778,610

(22) PCT Filed: Aug. 21, 2015
(86) PCT No.: PCT/CN2015/087727

§ 371 Date: Sep. 21, 2015

(30) Foreign Application Priority Data
Jul. 21, 2015 (CN) 201510432315.8

(51) Int. Cl. G09G 3/36; H01L 29/786; G02F 1/1345; H01L 27/12; G02F 1/1368; G02F 1/1362

(52) U.S. Cl. CPC G09G 3/3677; G02F 1/1368; G02F 1/136286; G02F 1/13454; H01L 27/124; H01L 27/1237; H01L 27/1222; H01L 29/78678; G09G 2300/0408; G02F 2202/104; G02F 2001/13685

(57) ABSTRACT

The present invention provides a GOA circuit structure for a slim-bezel LCD, including: a latch, a NAND gate, a buffer unit, and a reset unit. An input signal is supplied to the latch and an output signal is supplied from the buffer unit. The buffer unit includes a plurality of TFTs formed of a first metal layer (1), a second metal layer (2), and an active layer (3) arranged between the first metal layer (1) and the second metal layer (2). Each of the TFTs includes a dual-gate arrangement including a bottom gate formed of the first metal layer (1), a source and a drain formed of the second metal layer (2), and a top gate also formed of the second metal layer (2) so that the size of the TFT of the buffer unit can be reduced, the width of buffer unit can be reduced, thereby reducing the width of the GOA circuit and allowing a bezel of the LCD to be slimmer.

### BACKGROUND OF THE INVENTION

1. Field of the Invention

The present invention relates to the field of display technology, and in particular to a GOA (Gate Driver on Array) circuit structure for a slim-bezel LCD (Liquid Crystal Display).

2. The Related Arts

Liquid crystal displays have a variety of advantages, such as thin device body, low power consumption, and being free of radiation, and are thus used widely, such as liquid crystal televisions, mobile phones, personal digital assistants (PDAs), digital cameras, computer monitors, and notebook computer screens, making it dominating the flat panel display field.

Most of the LCDs that are currently available in the market are backlighting LCDs, which comprise a liquid crystal display panel and a backlight module. The operation principle of the LCDs is that liquid crystal molecules are filled between a thin-film transistor (TFT) array substrate and a color filter (CF) substrate and a driving voltage is applied to the two substrates to control the liquid crystal molecules to rotate in order to refract out light from the backlight module to generate an image.

In an active liquid crystal display, each pixel is electrically connected to a TFT in such a way that a gate of the TFT is connected to a horizontal scan line, a drain connected to a data line in a vertical direction, and a source connected to a pixel electrode. A sufficient voltage is applied to the horizontal scan line to have all the TFTs that are electrically connected to the horizontal scan line conducted on so that a signal voltage of the data line can be written into the pixels to control light transmittal of different parts of the liquid crystal thereby achieving an effect of controlling color and brightness. GOA, which refers to a technology of Gate Driver on Array, uses an array manufacturing process of the liquid crystal display panel to make a gate drive circuit on the TFT array substrate in order to achieve a line-by-line scanning method of the gate electrodes. The GOA circuit has advantages of reducing cost and enabling a slim bezel design, making it fit for the liquid crystal displays.

According to the difference of the materials of active layers, the GOA circuits can be classified as an amorphous silicon (a-Si) GOA circuit, an indium gallium zinc oxide (IGZO) GOA circuit, and a low temperature poly-silicon (LTPS) GOA circuit. Each of the GOA circuits uses a different manufacturing process. LTPS has the advantages of high electron mobility and being a mature technique and is widely used in the GOA circuits of medium- and small-sized LCDs.

With the progress of techniques, the requirement for aesthetics has been increasingly server for LCDs. The width of a front bezel is a factor for the aesthetics and is paid much attention by the LCD manufacturers. A variety of factors may affect a bezel width of an LCD, such as bezel material, cutting techniques, and precision of machines. In addition to these factors, the width of the GOA circuit is also an important factor of influence.

FIG. 1 is a schematic view illustrating the basic operation principle of a GOA circuit. The GOA circuit has two basic functions. The first one is the function of input of gate pulses for driving gate lines contained in a panel to conduct on TFTs within a display zone so that data lines may charge pixels. The second one is the function of shift registering, wherein when the output of an nth gate pulse (G(n)) is completed, an (n+1)th gate pulse (G(n+1)) can be controlled by a clock signal to output and so on.

FIG. 2 is a block diagram showing the basic structure of a GOA circuit with a CMOS (Complementary Metal-Oxide-Semiconductor) manufacturing process. The GOA circuit comprises four parts: a latch, a NAND gate, a buffer unit, and a reset unit. The latch is electrically connected to the NAND gate and the reset unit. The NAND gate is electrically connected to the latch and the buffer unit. The reset unit receives an input of a reset signal. An input signal and a first clock signal are supplied to the latch. A second clock signal is fed to the NAND gate. An output signal is supplied from the buffer unit. Since an output stage of the buffer unit requires a powerful driving capability, a TFT contained in the buffer unit is often of a large size, occupying a large amount of a lay-out space, making it adverse to reduction of the bezel width of an LCD.

Referring collectively to FIGS. 3 and 4, the buffer unit of a conventional GOA circuit comprises a plurality of TFTs made up of a first metal layer 10, a second metal layer 20, and an active layer 30 arranged between the first metal layer 10 and the second metal layer 20. Each of the TFTs has a gate that is formed of the first metal layer 10 and each of the TFTs has a source and a drain that are formed of the second metal layer 20 in such a way that the source and the drain are respectively located on two sides of the gate. The active layer 30 has zones that correspond to the source and drain of the TFT and are heavily ion doped zones 301 and the source and drain of the TFT are respectively connected through vias 601 to the heavily ion doped zones 301 of the active layer 30. A portion of the active layer 30 that corresponds to a zone between the source and drain of the TFT is a channel zone 302. Since the conventional buffer unit uses only the first metal layer 10 to form the gate of the TFT and the channel zone 302 of the active layer 30 is set above the gate with a small thickness and large resistance, to enhance the driving capability of the buffer unit, it often needs to increase the length of the channel zone 302. Although this way effectively increases the driving capability of the buffer unit, the width of the buffer unit is increased also and correspondingly, the width of the GOA circuit is increased, making it adverse to the reduction of the width of the bezel of the LCD.

### SUMMARY OF THE INVENTION

An object of the present invention is to provide a GOA (Gate Driver on Array) circuit structure for a slim-bezel LCD (Liquid Crystal Display), which reduces the size of a thin-film transistor (TFT) within a buffer unit and a width of the buffer unit so as to reduce a width of the GOA circuit to make the front bezel of the LCD slim.

To achieve the above object, the present invention provides a GOA circuit structure for a slim-bezel LCD, which comprises a latch, a NAND gate, a buffer unit, and a reset unit, the latch being electrically connected to the NAND gate and the reset unit, the NAND gate being electrically connected to the latch and the buffer unit, an input signal being supplied to the latch, an output signal being supplied from the buffer unit,

wherein the buffer unit comprises a plurality of TFTs formed of a first metal layer, a second metal layer, and an active layer arranged between the first metal layer and the second metal layer, each of the TFTs comprising a dual-gate arrangement, which comprises a bottom gate formed of the first metal layer, a source and a drain formed of the second metal layer, and a top gate also formed of the second metal layer.

The source and the drain are respectively located on two sides of the bottom gate and the top gate; the active layer has zones that respectively correspond to the source and the drain of the TFT and are heavily ion doped zones and the active layer has a portion corresponding to a zone between the source and the drain of the TFT and forming a channel zone

The source and the drain of the TFT are each connected by a via to the heavily ion doped zones of the active layer.

A bottom gate insulation layer is further arranged between the first metal layer and the active layer and a top gate insulation layer is further arranged between the active layer and the second metal layer; and the vias extend through the top gate insulation layer.

The first metal layer is formed of a material comprising one of molybdenum, titanium, aluminum, copper, and nickel or a stacked combination of multiple ones thereof.

The second metal layer is formed of a material comprising one of molybdenum, titanium, aluminum, copper, and nickel or a stacked combination of multiple ones thereof.

The active layer is formed of a material of poly-silicon.

The bottom gate insulation layer and the top gate insulation layer are formed of a material comprising silicon oxide, silicon nitride, or a combination thereof.

The present invention also provides a GOA circuit structure for a slim-bezel LCD, which comprises a latch, a NAND gate, a buffer unit, and a reset unit, the latch being electrically connected to the NAND gate and the reset unit, the NAND gate being electrically connected to the latch and the buffer unit, an input signal being supplied to the latch, an output signal being supplied from the buffer unit,

wherein the buffer unit comprises a plurality of TFTs formed of a first metal layer, a second metal layer, and an active layer arranged between the first metal layer and the second metal layer, each of the TFTs comprising a dual-gate arrangement, which comprises a bottom gate formed of the first metal layer, a source and a drain formed of the second metal layer, and a top gate also formed of the second metal layer;

wherein the first metal layer is formed of a material comprising one of molybdenum, titanium, aluminum, copper, and nickel or a stacked combination of multiple ones thereof;

wherein the second metal layer is formed of a material comprising one of molybdenum, titanium, aluminum, copper, and nickel or a stacked combination of multiple ones thereof; and

wherein the active layer is formed of a material of poly-silicon.

The efficacy of the present invention is that the present invention provides a GOA circuit structure for a slim-bezel LCD, which comprises a buffer unit having therein a TFT that comprises a bottom gate formed of a first metal layer and located under a channel zone of an active layer and a top gate formed of a second metal layer and located above the channel zone of the active layer and the channel zone of the active layer has a large thickness and thus reduced resistance so as to significantly increase the driving capability of the TFT of the buffer unit. Under the condition of identical driving capability, the size of the TFT of the buffer unit can be reduced thereby reducing the width of the buffer unit, and reducing the with of the GOA circuit, and allowing a bezel of the LCD to be made slimmer.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIG. 1 is a schematic view illustrating the basic operation principle of a GOA (Gate Driver on Array) circuit;

FIG. 2 is a block diagram showing a basic structure of a GOA circuit with a CMOS (Complementary Metal-Oxide-Semiconductor) manufacturing process;

FIG. 3 is a top plan view of a buffer unit of a conventional GOA circuit;

FIG. 4 is a schematic view illustrating a cross-section of FIG. 3 taken along line A-A;

FIG. 5 is a top plan view showing a GOA circuit structure for a slim-bezel LCD (Liquid Crystal Display) according to the present invention; and

FIG. 6 is a schematic view illustrating a cross-section of FIG. 5 taken along line B-B.

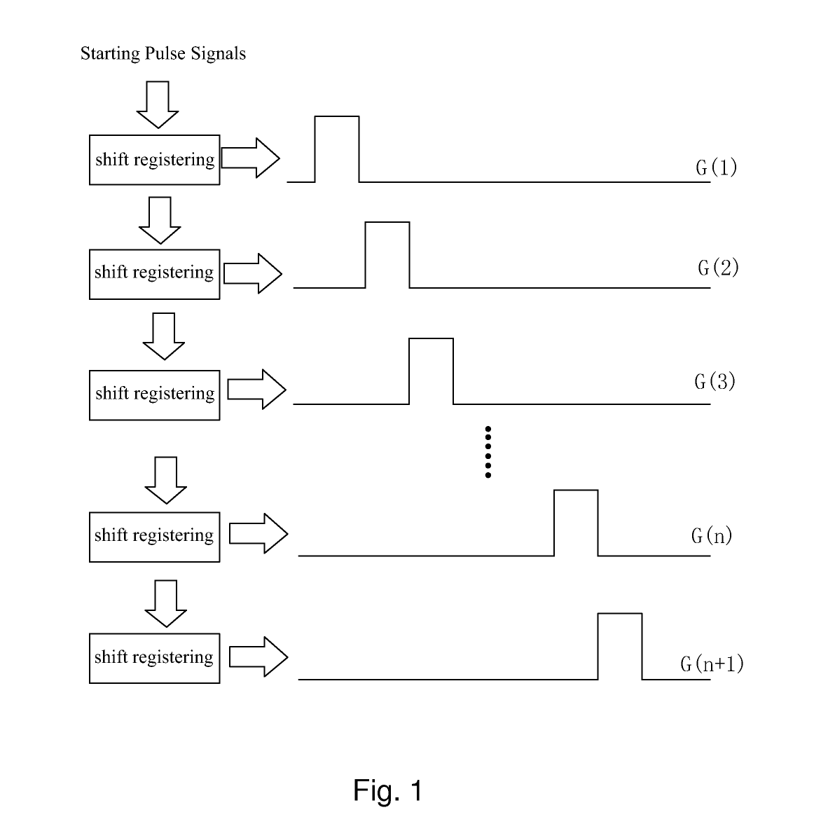

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

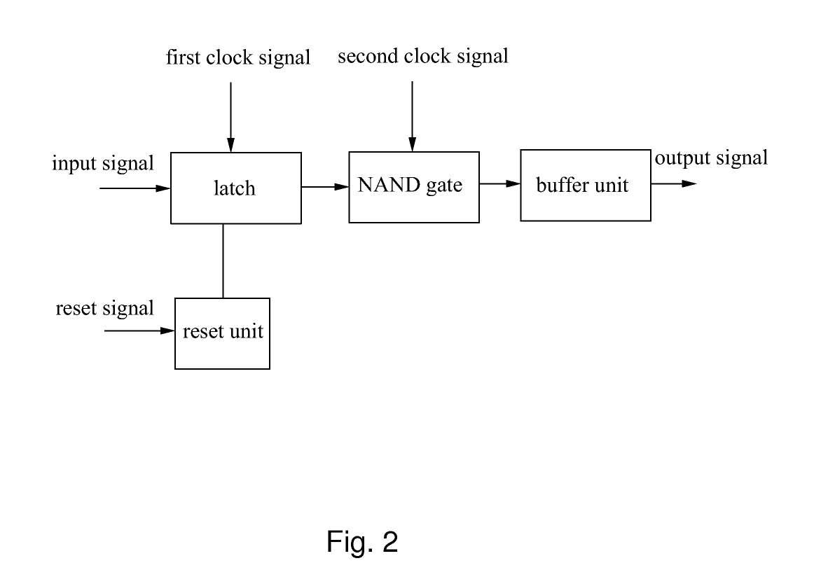

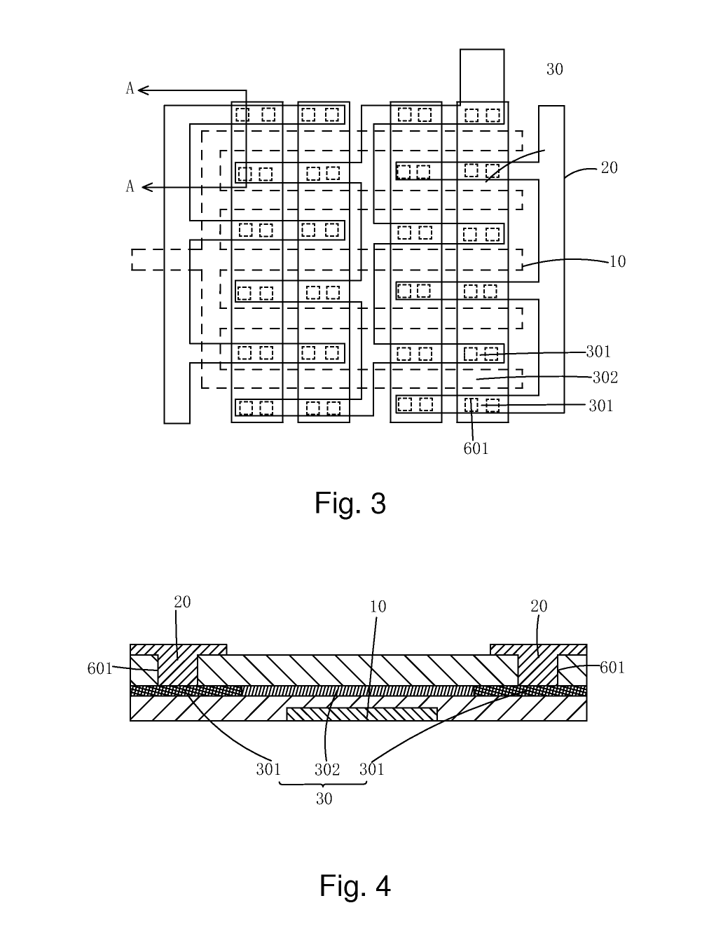

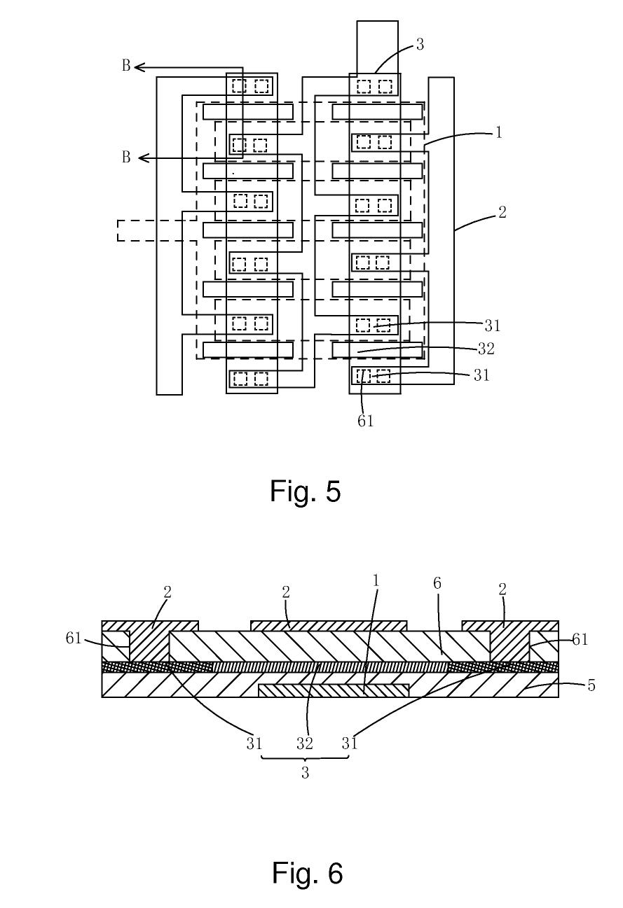

The present invention provides a GOA (Gate Driver on Array) circuit structure for a slim-bezel LCD (Liquid Crystal Display). Referring to FIGS. 2, 5, and 6, the GOA circuit structure of the present invention comprises: a latch, a NAND gate, a buffer unit, and a reset unit. The latch is electrically connected to the NAND gate and the reset unit. The NAND gate is electrically connected to the latch and the buffer unit. An input signal and a first clock signal are supplied to the latch and a second clock signal is fed to the NAND gate. An output signal is supplied from the buffer unit.

The buffer unit comprises a plurality of TFTs (Thin-Film Transistors) that is made up of a first metal layer 1, a second metal layer 2, and an active layer 3 arranged between the first metal layer 1 and the second metal layer 2. Each of the TFTs comprises a dual-gate arrangement that comprises a bottom gate formed of the first metal layer 1, a source and a drain formed of the second metal layer 2, and a top gate also formed of the second metal layer 2.

Specifically, the source and the drain are respectively located on two sides of the bottom gate and the top gate. The active layer 3 has zones that respectively correspond to the source and the drain of the TFT and are heavily ion doped zones 31. The active layer 3 has a portion corresponding to a zone between the source and the drain of the TFT and forming a channel zone 32.

Further arranged between the first metal layer 1 and the active layer 3 is bottom gate insulation layer 5 and further arranged between the active layer 3 and the second metal layer 2 is a top gate insulation layer 6. The source and the drain of the TFT are respectively connected by vias 61 that extend through the top gate insulation layer 6 to the heavily ion doped zones 31 of the active layer 3.

The first metal layer 1 is formed of a material comprising one of molybdenum, titanium, aluminum, copper, and nickel or a stacked combination of multiple ones thereof.

The second metal layer 2 is formed of a material comprising one of molybdenum, titanium, aluminum, copper, and nickel or a stacked combination of multiple ones thereof.

The active layer 3 is formed of a material of poly-silicon.

The bottom gate insulation layer 5 and the top gate insulation layer 6 are each formed of a material of silicon oxide (SiOx), silicon nitride (SiNx), or a combination thereof.

In the above-described buffer unit, the TFT comprises a bottom gate that is formed of the first metal layer 1 and located under the channel zone 32 of the active layer 3 and a top gate that is formed of the second metal layer 2 and located above the channel 32 of the active layer 3, the channel zone 32 of the active layer 3 having a large thickness and thus reduced resistance, so that the driving capability of the TFT of the buffer unit is significantly increased, whereby under the condition of identical driving capability, the size of the TFT of the buffer unit can be reduced and thus, the width of the buffer unit can be reduced and the width of the GOA circuit can be reduced to make it possible for a bezel of an LCD to be made even slimmer. For example, under the condition of identical driving capability, the buffer unit of a conventional GOA circuit has a width of around 300 μm, while the buffer unit of the GOA circuit structure of the present invention has a width that is reduced to around 150 μm so that compared to the prior art, the GOA circuit structure of the present invention allows the width of the GOA circuit and the width of the bezel of the LCD to be reduced by around 150 μm.

In summary, the present invention provides a GOA circuit structure for a slim-bezel LCD, which comprises a buffer unit having therein a TFT that comprises a bottom gate formed of a first metal layer and located under a channel zone of an active layer and a top gate formed of a second metal layer and located above the channel zone of the active layer and the channel zone of the active layer has a large thickness and thus reduced resistance so as to significantly increase the driving capability of the TFT of the buffer unit. Under the condition of identical driving capability, the size of the TFT of the buffer unit can be reduced thereby reducing the width of the buffer unit, and reducing the with of the GOA circuit, and allowing a bezel of the LCD to be made slimmer.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A gate-driver-on-array (GOA) circuit structure for a slim-bezel liquid crystal display (LCD), comprising a latch, a NAND gate, a buffer unit, and a reset unit, the latch being electrically connected to the NAND gate and the reset unit, the NAND gate being electrically connected to the latch and the buffer unit, an input signal being supplied to the latch, an output signal being supplied from the buffer unit,
wherein the buffer unit comprises a plurality of thin-film transistors (TFTs) formed of a first metal layer, a second metal layer, and an active layer arranged between the first metal layer and the second metal layer, each of the TFTs comprising a dual-gate arrangement, which comprises a bottom gate formed of the first metal layer, a source and a drain formed of the second metal layer, and a top gate also formed of the second metal layer.

2. The GOA circuit structure for a slim-bezel LCD as claimed in claim 1, wherein the source and the drain are respectively located on two sides of the bottom gate and the top gate; the active layer has zones that respectively correspond to the source and the drain of the TFT and are heavily ion doped zones and the active layer has a portion corresponding to a zone between the source and the drain of the TFT and forming a channel zone.

3. The GOA circuit structure for a slim-bezel LCD as claimed in claim 2, wherein the source and the drain of the TFT are each connected by a via to the heavily ion doped zones of the active layer.

4. The GOA circuit structure for a slim-bezel LCD as claimed in claim 3, wherein a bottom gate insulation layer is further arranged between the first metal layer and the active layer and a top gate insulation layer is further arranged between the active layer and the second metal layer; and the vias extend through the top gate insulation layer.

5. The GOA circuit structure for a slim-bezel LCD as claimed in claim 1, wherein the first metal layer is formed of a material comprising one of molybdenum, titanium, aluminum, copper, and nickel or a stacked combination of multiple ones thereof.

6. The GOA circuit structure for a slim-bezel LCD as claimed in claim 1, wherein the second metal layer is formed of a material comprising one of molybdenum, titanium, aluminum, copper, and nickel or a stacked combination of multiple ones thereof.

7. The GOA circuit structure for a slim-bezel LCD as claimed in claim 1, wherein the active layer is formed of a material of poly-silicon.

8. The GOA circuit structure for a slim-bezel LCD as claimed in claim 4, wherein the bottom gate insulation layer and the top gate insulation layer are formed of a material comprising silicon oxide, silicon nitride, or a combination thereof.

9. A gate-driver-on-array (GOA) circuit structure for a slim-bezel liquid crystal display (LCD), comprising a latch, a NAND gate, a buffer unit, and a reset unit, the latch being electrically connected to the NAND gate and the reset unit, the NAND gate being electrically connected to the latch and the buffer unit, an input signal being supplied to the latch, an output signal being supplied from the buffer unit,
wherein the buffer unit comprises a plurality of thin-film transistors (TFTs) formed of a first metal layer, a second metal layer, and an active layer arranged between the first metal layer and the second metal layer, each of the TFTs comprising a dual-gate arrangement, which comprises a bottom gate formed of the first metal layer, a source and a drain formed of the second metal layer, and a top gate also formed of the second metal layer;
wherein the first metal layer is formed of a material comprising one of molybdenum, titanium, aluminum, copper, and nickel or a stacked combination of multiple ones thereof;
wherein the second metal layer is formed of a material comprising one of molybdenum, titanium, aluminum, copper, and nickel or a stacked combination of multiple ones thereof; and
wherein the active layer is formed of a material of poly-silicon.

10. The GOA circuit structure for a slim-bezel LCD as claimed in claim 9, wherein the source and the drain are respectively located on two sides of the bottom gate and the top gate; the active layer has zones that respectively correspond to the source and the drain of the TFT and are heavily ion doped zones and the active layer has a portion corresponding to a zone between the source and the drain of the TFT and forming a channel zone.

11. The GOA circuit structure for a slim-bezel LCD as claimed in claim 10, wherein the source and the drain of the TFT are each connected by a via to the heavily ion doped zones of the active layer.

12. The GOA circuit structure for a slim-bezel LCD as claimed in claim 11, wherein a bottom gate insulation layer is further arranged between the first metal layer and the active layer and a top gate insulation layer is further arranged between the active layer and the second metal layer; and the vias extend through the top gate insulation layer.

13. The GOA circuit structure for a slim-bezel LCD as claimed in claim 12, wherein the bottom gate insulation layer and the top gate insulation layer are formed of a material comprising silicon oxide, silicon nitride, or a combination thereof.
